(19) United States
(12) Patent Application Publication
(10) Pub. No.: US 2026/0333589 A1
(43) Pub. Date: Oct. 22, 2026

(54) SHEET MATERIAL POSITIONING DEVICE, POSITIONING METHOD, AND SHIELD LAYER FORMATION METHOD FOR ELECTRONIC COMPONENT

(71) Applicant: TOWA CORPORATION, Kyoto-shi, Kyoto (JP)

(72) Inventors: Shun HIRANO, Kyoto-shi (JP); Ryo NISHIHARA, Kyoto-shi (JP)

(73) Assignee: TOWA CORPORATION, Kyoto-shi, Kyoto (JP)

(21) Appl. No.: 19/107,646

(22) PCT Filed: Mar. 22, 2023
(86) PCT No.: PCT/JP2023/011307

§ 371 Date: Feb. 28, 2025

(30) Foreign Application Priority Data
Sep. 6, 2022 (JP) 2022-141533

(51) Int. Cl. H05K 3/22; H05K 9/00

(52) U.S. Cl. CPC H05K 3/22; H05K 9/0081

(57) ABSTRACT

A positioning device for a sheet material according to the present invention is a positioning device for a sheet material including a base material and a functional material disposed on the base material, the positioning device including: a support mechanism that supports the sheet material; a sheet table that fixes the sheet material; and a detection unit that detects a position in a plane direction of the functional material in the sheet material supported by the support mechanism, wherein the sheet material is fixed to the sheet table after positioning of relatively moving the sheet material with respect to the sheet table is completed such that the functional material is disposed at a predetermined position with respect to the sheet table based on the position of the functional material detected by the detection unit.

### TECHNICAL FIELD

The present invention relates to a sheet material positioning device, a positioning method, and a method for forming a shield layer with respect to an electronic component.

### BACKGROUND ART

PTL 1 discloses a conveyance mechanism that fixes a release film cut into a predetermined length to a sheet table and then conveys the release film to a resin molding apparatus. More specifically, the release film is unwound from a roll by a predetermined length, then cut, and fixed to the sheet table. Thereafter, the release film having a predetermined length is conveyed to the resin molding apparatus by the conveyance mechanism.

### CITATION LIST

### Patent Literature

PTL 1: Japanese Patent No. 6423399

### SUMMARY OF INVENTION

### Technical Problem

However, the release film is not positioned with respect to the sheet table with high accuracy, and is merely disposed on the sheet table. Thus, such a mechanism is not appropriate for equipment in which accuracy is required for the position of the release film in the subsequent steps. Such a problem is a problem that may occur not only with a release film but also with all sheet materials that require highly accurate positioning with respect to the sheet table. In addition, the process after conveyance as described above is not limited to the resin molding apparatus, and various processes may be applied.

The present invention has been made to solve this problem, and an object of the present invention is to provide a sheet material positioning device, a positioning method, and a method for forming a shield layer with respect to an electronic component, which are capable of positioning with high accuracy when a sheet material is disposed on a sheet table.

### Solution to Problem

A positioning device for a sheet material according to the present invention is a positioning device for a sheet material including a base material and a functional material disposed on the base material, the positioning device including: a support mechanism that supports the sheet material; a sheet table that fixes the sheet material; and a detection unit that detects a position in a plane direction of the functional material in the sheet material supported by the support mechanism, wherein the sheet material is fixed to the sheet table after positioning of relatively moving the sheet material with respect to the sheet table is completed such that the functional material is disposed at a predetermined position with respect to the sheet table based on the position of the functional material detected by the detection unit.

A method for positioning a sheet material according to the present invention is a method for positioning a sheet material including a base material and a functional material disposed on the base material, the method including: disposing the sheet material above a sheet table; detecting a position in a plane direction of the functional material in the sheet material; performing positioning of relatively moving the sheet material with respect to the sheet table based on the position of the functional material that has been detected such that the functional material is disposed at a predetermined position with respect to the sheet table; and fixing the sheet material to the sheet table after the positioning is completed.

A method for forming a shield layer with respect to an electronic component according to the present invention includes: preparing a first mold and a second mold that face each other; after the method for positioning a sheet material described above, conveying the sheet material from the sheet table via a conveyance mechanism to dispose the sheet material on an installation surface of the first mold in a state where the functional material faces the second mold; disposing a plurality of electronic components on the carrier at a predetermined interval; disposing the carrier on an installation surface of the second mold in a state where the electronic components face the first mold; and bringing the first mold and the second mold close to each other, and pressure-bonding the functional material against surfaces of the electronic components to form a shield layer on the surface of the electronic components, wherein the functional material is an electromagnetic wave shielding material.

### Advantageous Effects of Invention

According to the present invention, positioning can be performed with high accuracy when the sheet material is disposed on the sheet table.

### BRIEF DESCRIPTION OF DRAWINGS

FIG. 1 is a plan view schematically illustrating a resin molding apparatus.

FIG. 2 is a sectional view of an electronic component.

FIG. 3 is a sectional view illustrating a carrier on which an electronic component is disposed.

FIG. 4 is a sectional view of a support member that supports a carrier.

FIG. 5 is a plan view of a sheet material wound as a roll.

FIG. 6 is a side view of FIG. 5.

FIG. 7 is a side view of a positioning device.

FIG. 8 is a plan view of FIG. 7.

FIG. 9 is a side view illustrating an operation of the positioning device.

FIG. 10 is a side view illustrating an operation of the positioning device.

FIG. 11 is a side view illustrating an operation of the positioning device.

FIG. 12 is a side view illustrating an operation of the positioning device.

FIG. 13 is a plan view illustrating an operation of the positioning device.

FIG. 14 is a side view illustrating an operation of the positioning device.

FIG. 15 is a sectional view for describing an operation of transferring a sheet material from a sheet table to a conveyance body.

FIG. 16 is a sectional view for describing the operation of transferring the sheet material from the sheet table to the conveyance body.

FIG. 17 is a sectional view for describing the operation of transferring the sheet material from the sheet table to the conveyance body.

FIG. 18 is a sectional view for describing the operation of transferring the sheet material from the sheet table to the conveyance body.

FIG. 19 is a sectional view illustrating an upper mold and a lower mold of a module B.

FIG. 20 is a sectional view illustrating a pressure bonding step for a shielding material.

FIG. 21 is a sectional view illustrating the pressure bonding step for the shielding material.

FIG. 22 is a sectional view illustrating the pressure bonding step for the shielding material.

FIG. 23 is a perspective view illustrating an operation of another example of the positioning device.

FIG. 24 is a perspective view illustrating an operation of another example of the positioning device.

FIG. 25 is a perspective view illustrating an operation of another example of the positioning device.

FIG. 26 is a perspective view illustrating an operation of another example of the positioning device.

FIG. 27 is a sectional view illustrating another example of the lower mold of the module B.

FIG. 28 is a plan view illustrating another example of the lower mold of the module B.

### DESCRIPTION OF EMBODIMENTS

Hereinafter, an embodiment of a system for forming a shield layer with respect to an electronic component including a sheet material positioning device according to the present invention will be described in detail with reference to the drawings. Each drawing may be schematically drawn with appropriate omission or exaggeration of the object for easy understanding.

### 1. Configuration of System for Forming Shield Layer With Respect to Electronic Component

FIG. 1 is a schematic plan view of a system 100 for forming a shield layer with respect to an electronic component according to the present embodiment. This system is a system for forming an electromagnetic wave shield layer on a surface of an electronic component. As illustrated in FIG. 1, the system 100 includes a module A, a module B, and a module C arranged from left to right in FIG. 1.

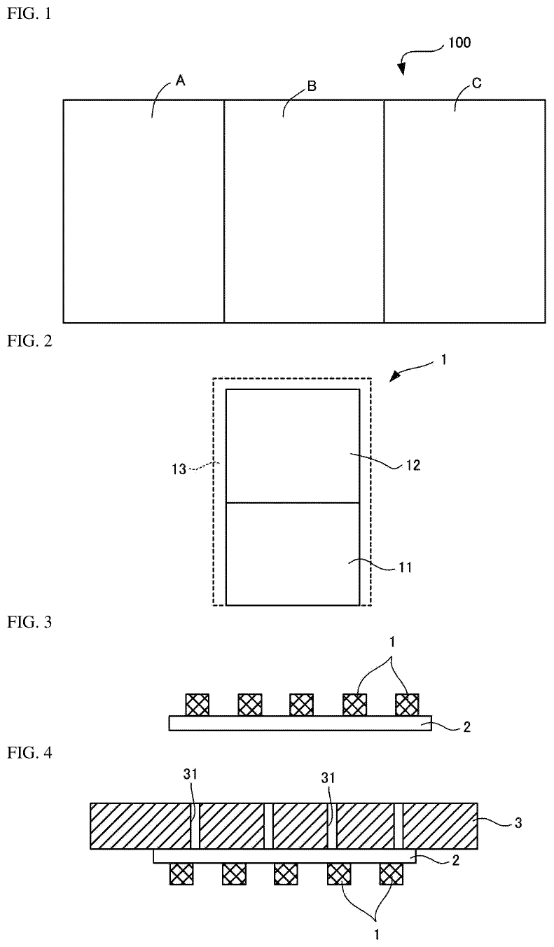

FIG. 2 is a sectional view of the electronic component on which the shield layer is formed. As illustrated in FIG. 2, this electronic component 1 includes a substrate 11 and a chip part 12 such as an IC chip disposed on the substrate 11. The substrate 11 may take various forms, and it may be, for example, a substrate that electrically relays a motherboard on which the electronic component 1 is mounted and the chip part 12, for example, an interposer. Specifically, a conductive pattern, a ground layer, an insulating layer, and the like (not illustrated) may be stacked. Then, as described later, a shield layer 13 is pressure-bonded to a top surface and a side surface of the chip part 12 and a side surface of the substrate 11 in the electronic component 1. Hereinafter, each module constituting the present system 100 will be described.

### 2. Module A

The module A is a handler module in which a plurality of electronic components are disposed on a carrier. As illustrated in FIG. 3, in this module A, a carrier 2 in which a plurality of electronic components 1 are disposed is prepared.

The carrier 2 may be formed of a film, a sheet, a substrate, or the like on which the electronic component 1 can be mounted, and it is sufficient that the carrier 2 can withstand a decompression step and heating described later. For example, the carrier 2 may be formed of metal, glass, or the like. A bonding layer or a pressure-sensitive adhesion layer for bonding the electronic component 1 is formed on a surface of the carrier 2. Then, the substrate 11 of the electronic component 1 is fixed to such a bonding layer or pressure-sensitive adhesion layer.

The number of electronic components 1 disposed on the carrier 2 is not particularly limited as long as it is one or more. In the present embodiment, N×M (N and M are integers of 2 or more) of electronic components 1 are disposed in an array.

As illustrated in FIG. 4, such a carrier 2 is supported by a support member 3 formed in a plate shape to be conveyed to the module B. A plurality of suction ports 31 are open on a lower surface of the support member 3, and the suction ports 31 suck the surface of the carrier 2 opposite to the surface on which the electronic component 1 is disposed. The support member 3 sucking the carrier 2 in this manner is conveyed to the module B by a conveyance device (not illustrated).

### 3. Module C

The module C will be described before the module B. The module C is a module that prepares an electromagnetic wave shielding material (functional material) to be pressure-bonded to the surface of the electronic component 1. First, a sheet material to which the shielding material is attached will be described.

### <3-1. Sheet Material>

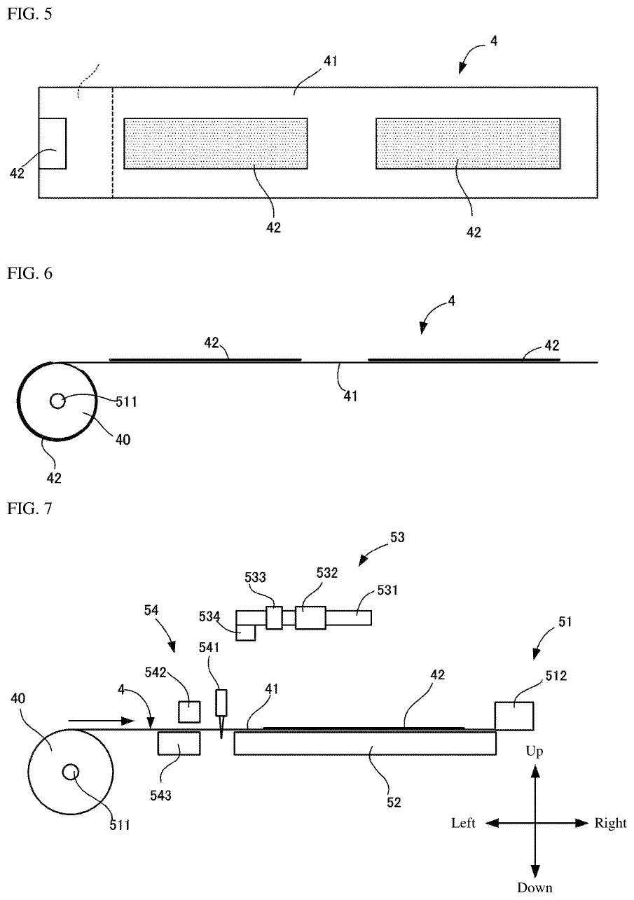

FIG. 5 is a plan view of a wound sheet material, and FIG. 6 is a side view of FIG. 5. As illustrated in FIGS. 5 and 6, a sheet material 4 is wound and held as a roll 40, including a sheet-like base material 41 and a plurality of shielding materials 42 disposed on the base material 41. The roll 40 that is the wound sheet material is rotatably held by a roll holder 511 as described later.

The base material 41 only needs to have releasability so that the shielding material 42 can be peeled off later, and it may be formed of a resin film or the like. The base material 41 particularly preferably includes a stretchable base material. With the stretchability, when an upper mold 61 and a lower mold 62 are brought close to each other in the module B to be described later, the base material 41 exhibits stretchability and can stretch in conformity with the shape of the electronic component 1. The base material 41 may be formed of a thermoplastic resin having cushioning properties.

The thickness of the base material 41 is not particularly limited. The thickness may be, for example, 50 to 550 μm, preferably 50 to 400 μm, and more preferably 100 to 350 μm. As a material constituting the base material 41, for example, thermoplastic polystyrene, polymethylpentene, poly butylene terephthalate, polypropylene, or a cyclic olefin polymer is preferably used. A cyclic olefin polymer is further preferable, and polymethylpentene is particularly preferable.

The shielding material 42 is formed in a rectangular shape having a width narrower than the width of the base material 41. A plurality of shielding materials 42 are disposed on the base material 41 at predetermined intervals in the unwinding direction of the roll 40. The shielding material is a sheet-like member for forming a shielding layer on the surface of the electronic component 1, which shields the electronic component 1 from electromagnetic waves. The shielding material 42 may contain, for example, a binder resin, a crosslinking agent, and a conductive filler, and it may further contain another additive as necessary.

The binder resin preferably contains, for example, a thermosetting resin selected from an epoxy-based resin, a phenol-based resin, an alkyd-based resin, a melamine-based resin, an acrylate-based resin, a silicone-based resin, or a mixture thereof.

The crosslinking agent is used to crosslink the binder resin. Specific examples thereof include those containing one or more structures of a hydroxyl group, a phenol, a carboxylic acid, an amine, an epoxy, an isocyanate, and an aziridine, and those containing an epoxy, a phenol, a hydroxyl group, and a carboxylic acid are preferable from the viewpoint of product life and reactivity.

Examples of the conductive filler include (1) metal powder of a conductive metal such as gold, copper, silver, or nickel, (2) alloy powder of an alloy of conductive metals, and (3) core-shell type particles of silver-coated copper powder, gold-coated copper powder, silver-coated nickel powder, and gold-coated nickel powder. The shape of the conductive filler may be a spherical shape, an elliptical spherical shape, a scaly shape, a dendrite shape, a grape shape, and/or a needle shape.

### <3-2. Sheet Material Positioning Device>

Next, a sheet material positioning device 5 provided in the module C will be described. FIG. 7 is a side view of the positioning device, and FIG. 8 is a plan view of FIG. 7. The positioning device 5 is a device that cuts out the sheet material 4 having a predetermined length from the roll 40 and disposes the sheet material 4 on the sheet table 52. As illustrated in FIGS. 7 and 8, the positioning device 5 includes a support mechanism 51 that supports the sheet material 4, the sheet table 52 that fixes the sheet material 4, a sensor unit 53 that detects the position of the shielding material 42 of the sheet material 4, and a cutting mechanism (cutting part) 54 that cuts the sheet material 4. These configurations are controlled by a controller (not illustrated) configured by a computer such as a PLC. Hereinafter, these configurations will be described in detail. Hereinafter, for convenience of description, description will be made according to the directions illustrated in FIGS. 7 and 8, but the positioning device according to the present invention is not limited to the directions.

### <3-2-1. Support Mechanism>

The support mechanism 51 includes a roll holder 511 that rotatably holds the roll 40 that is the wound sheet material 4, and a feeder 512 that holds an end of the sheet material 4 and approaches and separates from the roll 40 in a left-right direction (first direction). The roll holder 511 includes a bearing (not illustrated) that rotatably supports the roll 40 and a driver (not illustrated) that drives the bearing. The feeder 512 is configured to be movable in the left-right direction. Specifically, the feeder 511 unwinds the sheet material 4 from the roll 40 by moving to the right side while holding the end of the sheet material 4 wound as the roll 40 with a chuck. When the sheet material 4 is unwound in this manner, as illustrated in FIG. 8, one shielding material 42 is exposed at the unwound sheet material 4.

### <3-2-2. Sheet Table>

The sheet table 52 is formed in a rectangular shape in plan view, and is disposed below the sheet material 4 unwound from the roll 40. A plurality of suction ports (not illustrated) are formed on the upper surface of the sheet table 52, and the sheet table sucks the sheet material 4 at the upper surface of the sheet table 52 by sucking air from the suction ports. The sheet table 52 is movable in the horizontal direction (paper surface direction of FIG. 8) while holding the sheet material 4, and is configured to convey the sheet material 4 to the module B described above.

### <3-2-3. Sensor Unit>

The sensor unit 53 is disposed above the sheet material 4 unwound from the roll 40. The sensor unit 53 includes a base 531 formed in a plate shape and supported to be movable in an up-down direction, and a first sensor 532 and a second sensor 533 disposed on the base 531. On the lower surface of the base 531, a first pressing part 534 extending in a front-back direction is provided at the end on the left side (roll 40 side). The first pressing part 534 comes into contact with the vicinity of the left end of the upper surface of the sheet table 52 as the base 531 descends. This makes it possible to sandwich the unwound sheet material 4 between the sheet table 52 and the first pressing part 534.

The sensor unit 53 is configured to come close to the upper surface of the sheet material 4 unwound from the roll 40 detect the position of the shielding material 42 in the horizontal direction. Specifically, the first sensor 532 detects an end edge extending in the left-right direction on the back side of the shielding material 42, and the second sensor 533 detects an end edge extending in the front-back direction on the left side of the shielding material 42. Then, the controller described above determines whether the detected end edge is disposed within a predetermined range.

### <3-2-4. Cutting Mechanism>

The cutting mechanism 54 is configured to cut the left side of the sheet material 4 unwound from the roll 40. More specifically, in the unwound sheet material 4, a portion away from the left end edge of the exposed shielding material 42 by a predetermined distance is cut in the front-back direction (second direction). That is, the base material 41 is cut between adjacent shielding materials 42. Thus, the cutting mechanism 54 includes a cutter 541 that cuts the sheet material 4, a second pressing part 542 that presses the sheet material 4 from above, and a support part 543 that supports the sheet material 4 from below. The second pressing part 542 and the support part 543 are formed so as to extend in the front-back direction between the sheet table 52 and the roll 40.

When the sheet material 4 is unwound, the left side of the unwound sheet material 4 is pressed by the second pressing part 542 and the support part 543. On the right side of the second pressing part 542 and the support part 543, the sheet material 4 is pressed by the first pressing part 534 and the sheet table 52. In this state, the base material 41 is cut by the cutter 541 moving in the front-back direction between the second pressing part 542 and the first pressing part 534. The means for cutting the sheet material may be other than the cutter 541. For example, the sheet material may be cut by heat such as a laser.

### <3-2-5. Operation of Positioning Device>

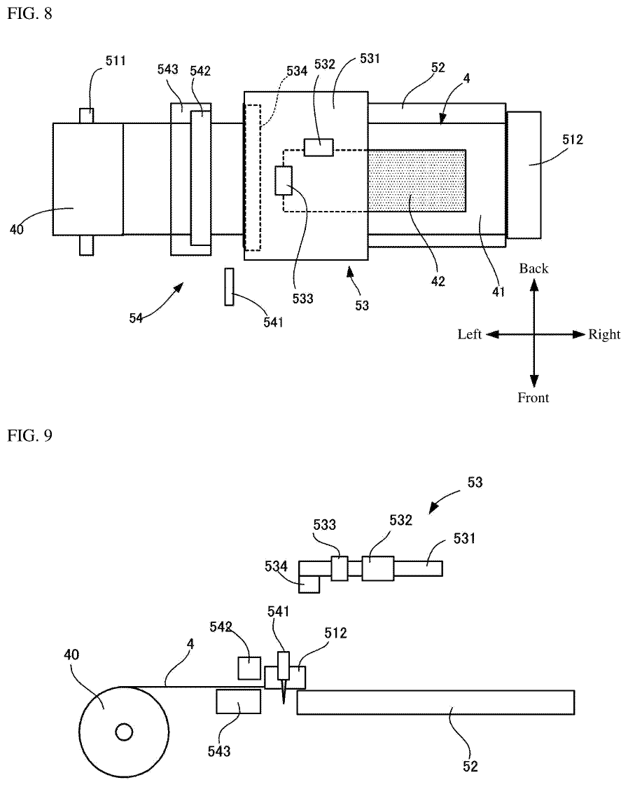

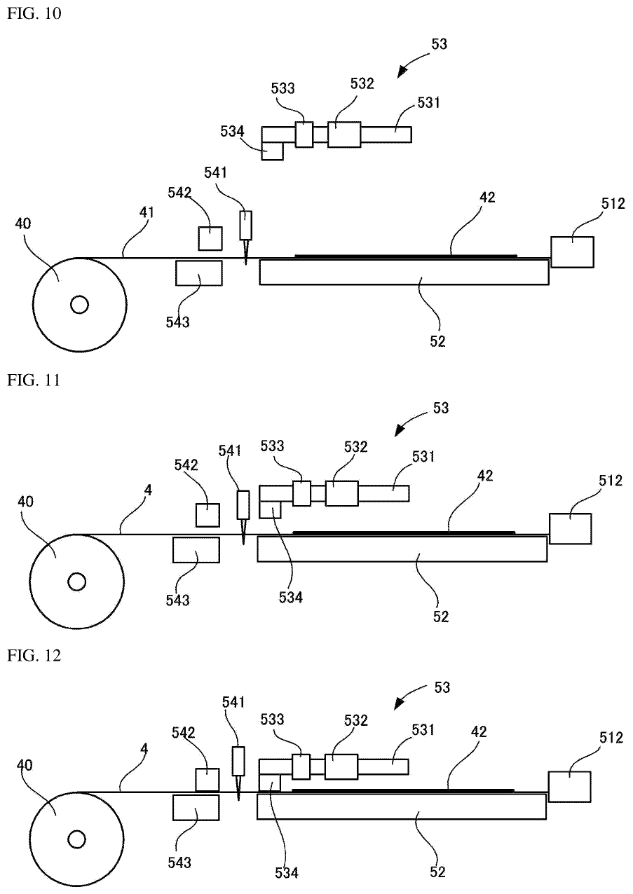

Next, an operation of the positioning device 5 configured as described above will be described with reference to FIGS. 9 to 14. First, as illustrated in FIG. 9, an end of the sheet material 4 wound as the roll 40 is held by the feeder 512. Next, as illustrated in FIG. 10, the feeder 512 moves to the right side to unwind the sheet material 4 from the roll 40. This causes one shielding material 42 in the unwound sheet material 4 to be disposed above the sheet table 52.

Next, as illustrated in FIG. 11, the sensor unit 53 descends and detects the position of the shielding material 42 with the first sensor 532 and the second sensor 533. That is, as illustrated in FIG. 8, the first sensor 532 and the second sensor 533 are disposed above the back and left end edges of the shielding material 42, respectively, and detect the positions of these end edges. At this time, when the detected position of the left end edge does not fall within a predetermined range, the roll holder 511 and the feeder 512 are driven to adjust the unwinding distance of the sheet material 4, thereby adjusting the position of the shielding material 42 in the left-right direction. This causes the shielding material 42 to be disposed at a predetermined position in the left-right direction with respect to the sheet table 52.

On the other hand, when the detected position of the back end edge does not fall within a predetermined range, the position of the sheet table 52 in the front-back direction is adjusted. This causes the shielding material 42 to be disposed at a predetermined position in the front-back direction with respect to the sheet table 52.

When the shielding material 42 is disposed at the predetermined position in this manner, as illustrated in FIG. 12, the sensor unit 53 further descends and presses the sheet material 4 with the first pressing part 534. This causes the base material 41 on the left side of the shielding material 42 to be sandwiched between the first pressing part 534 and the sheet table 52 at the sheet material 4. At the same time, air is sucked from the upper surface of the sheet table 52 to suck the sheet material 4. In addition, the second pressing part 542 descends with respect to the support part 543, and the second pressing part and the support part presses the left side from the first pressing part 534 of the sheet material 4. Subsequently, as illustrated in FIG. 13, the cutter 541 cuts a portion of the sheet material 4 between the first pressing part 534 and the second pressing part 542.

Subsequently, as illustrated in FIG. 14, the sensor unit 53 ascends, and the second pressing part 542 separates from the support part 543. The sheet-like sheet material 4 on which the shielding material 42 is correctly positioned with respect to the sheet table 52 is thus formed.

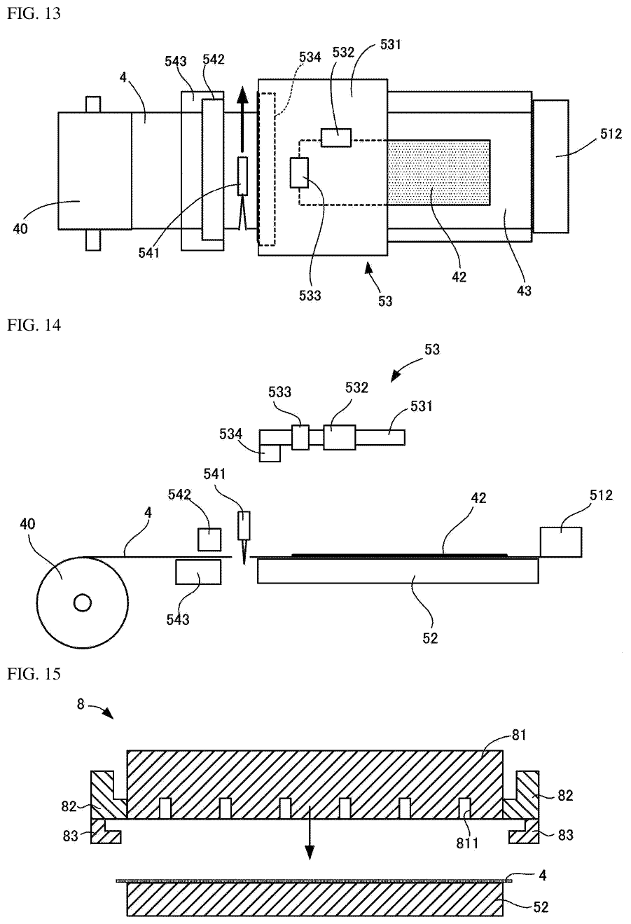

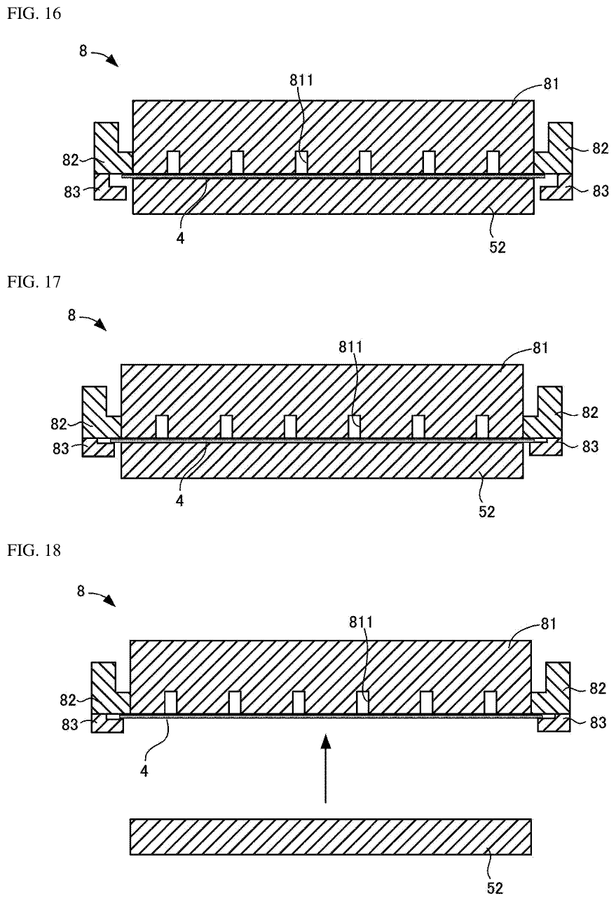

Next, the sheet material 4 on the sheet table 52 is transferred to the conveyance mechanism. This point will be described with reference to FIGS. 15 to 18. After the sheet material 4 is positioned on the sheet table 52 as described above, a conveyance body 8 of the conveyance mechanism is disposed above the sheet material 4 as illustrated in FIG. 15. The conveyance body 8 is movable between the modules B and C, including a main body 81 in which a plurality of suction ports 811 for holding the sheet material 4 are formed on the lower surface. A first holder 82 that sandwiches the main body 81 from the side is provided on a side surface of the main body 81, and a second holder 83 that can ascend and descend is provided at a lower portion of the first holder 82.

As illustrated in FIG. 16, the conveyance body 8 is positioned above the sheet table 52 and then descends. This causes the lower surface of the main body 81 to come into contact with the sheet material 4 on the sheet table 52. In this state, as illustrated in FIG. 17, the air sucked from the suction port 811 holds the sheet material 4, and at the same time the second holder 83 ascends, and the first and second holders 82 and 83 sandwiches the peripheral edge of the sheet material 4. Thereafter, air suction on the sheet table 52 is stopped, and the conveyance body 8 ascends as illustrated in FIG. 18. The sheet material 4 is thus transferred from the sheet table 52 to the conveyance body 8. In this state, the conveyance body 8 moves to convey the sheet material 4 to the module B.

Then, after the sheet table 52 is returned to the initial position of FIG. 8, the feeder 512 moves to the vicinity of the second pressing part 542 to hold the end of the sheet material 4, and the behavior of FIGS. 9 to 18 is repeated. The sheet-like sheet material 4 positioned at a predetermined position on the sheet table 52 is thus sequentially conveyed to the module B.

### 4. Module B

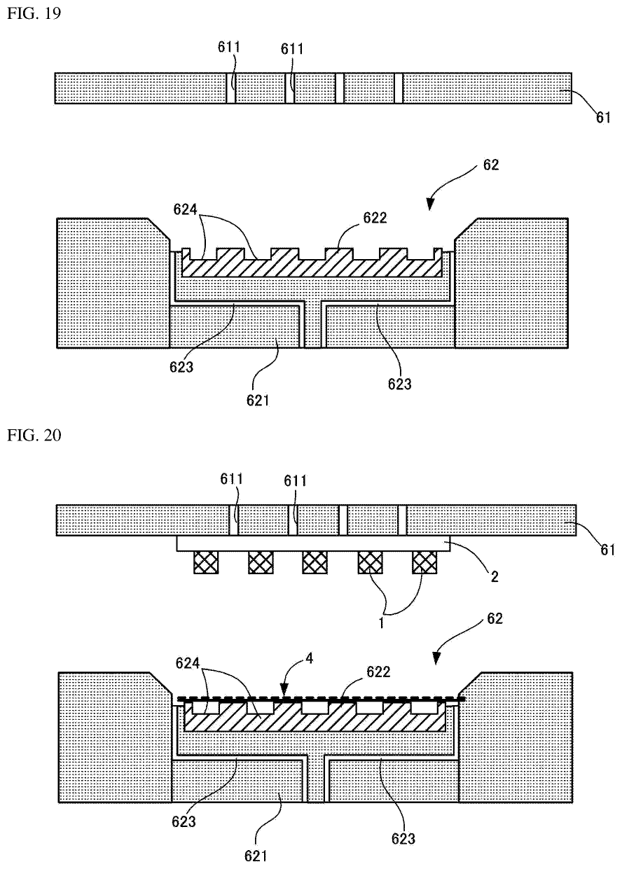

Next, the module B will be described. The module B is a module for pressure-bonding the shielding material 42 conveyed from the module C to the surface of the electronic component 1 conveyed from the module A. As illustrated in FIG. 19, the module B includes an upper mold (second mold) 61 on which the carrier 2 is to be disposed and a lower mold (first mold) 62 on which the sheet material 4 is to be disposed, and these are disposed in a decompressive chamber. Hereinafter, the upper mold 61 and the lower mold 62 will be described.

### <4-1. Overview of Upper Mold and Lower Mold>

As illustrated in FIG. 19, the lower surface of the upper mold 61 is formed flat so that the carrier 2 is disposed, and a plurality of suction ports 611 are formed on the lower surface. Then, the carrier 2 conveyed from the module A by the conveyance device is disposed on the lower surface of the upper mold 61 and sucked.

The lower mold 62 includes a base 621 having a rectangular upper surface and a rectangular support plate 622 disposed on the upper surface of the base 621. The support plate 622 is formed smaller than the upper surface of the base 621, and the suction port 623 is formed in a region outside the support plate 622 on the upper surface of the base 621. By sucking air from the suction port 623, the sheet material 4 conveyed from the module C is sucked.

A plurality of rectangular recesses 624 are formed on the upper surface of the support plate 622. These recesses 624 are formed at positions facing the electronic component 1 mounted to the upper mold 61 via the carrier 2. That is, each recess 624 is formed in a rectangular shape slightly larger than the planar shape of the electronic component 1, and when the upper mold 61 and the lower mold 62 come close to each other, each electronic component 1 enters the recess 624.

### <4-2. Pressure Bonding Step for Shielding Material With Upper Mold and Lower Mold>

Next, the pressure bonding step for the shielding material will be described with reference to FIGS. 20 to 22. First, as illustrated in FIG. 20, the carrier 2 is disposed on the upper mold 61, and the sheet material 4 is disposed on the lower mold 62. The sheet material 4 is positioned on the sheet table 52 in the module C and then conveyed to the module B by the conveyance body 8. With this positioning, when the sheet material 4 is transferred from the conveyance body 8 to the lower mold 62, the shielding material 42 of the sheet material 4 is disposed so as to cover all the recesses 624.

Next, the pressure inside the chamber is reduced. At this time, the degree of vacuum in the chamber may be set to 4000 Pa or less, preferably 2000 Pa or less, more preferably 1000 Pa or less, and still more preferably 100 Pa or less. Reducing the pressure in this manner makes it possible to firmly bring the electronic component 1 and the shielding material 42 in close contact with each other.

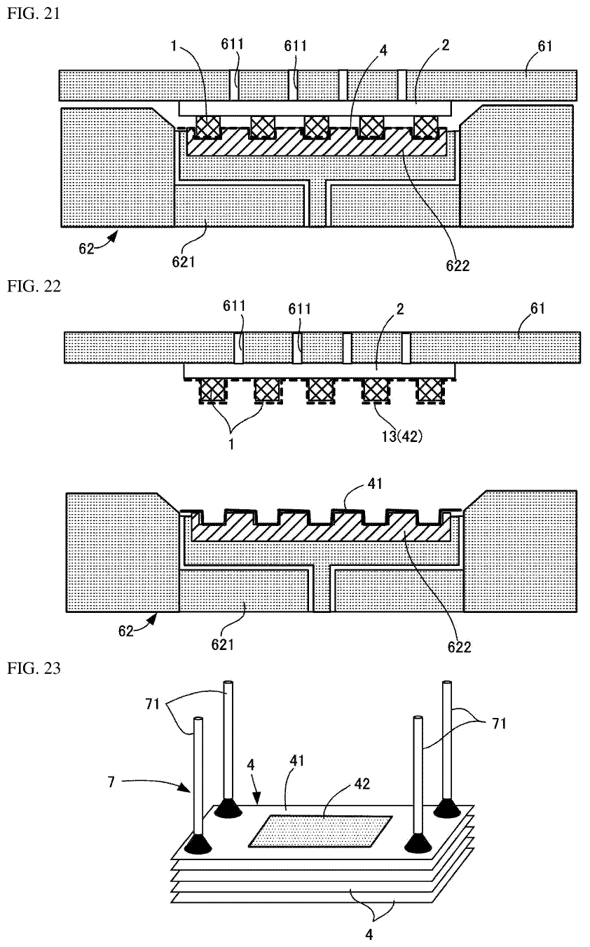

Subsequently, as illustrated in FIG. 21, the upper mold 61 and the lower mold 62 are brought close to each other, and each electronic component 1 is inserted into the recess 624. This causes the shielding material 42 to be brought into close contact with the surfaces (lower surface and side surface) of the electronic components 1. Subsequently, when the upper mold 61 and the lower mold 62 are heated, the shielding material 42 in close contact with the electronic component 1 is cured, and the shield layer 13 is formed on the lower surface and the side surface of the electronic component 1. The upper mold 61 and the lower mold 62 may be brought close to each other after being heated in advance.

Pressurization may be performed at the time of heating. For example, the electronic component 1 and the shielding material 42 may be pressurized by the upper mold 61 and the lower mold 62. The pressure at this time may be, for example, 1 to 10 MPa. This makes it possible to form the shield layer 13 more firmly and reliably on the electronic component 1.

The heating temperature and the cure time may be appropriately set depending on the conditions of the selected binder resin and the like, and may be, for example, 90 to 180 seconds at 100 to 180 °C. Here, the cure time may be a time from completion of mold clamping to the peeling described below. Instead of the above, mold clamping may be performed only by pressing under a normal temperature or room temperature environment without heating.

Then, as illustrated in FIG. 22, when the upper mold 61 and the lower mold 62 are separated from each other, the shielding material 42 of the sheet material 4 is peeled off from the base material 41 and transferred to the electronic component 1. The electronic component 1 on which the shield layer 13 is formed is thus obtained.

Subsequently, the carrier 2 is removed from the upper mold, and the carrier 2 on which each electronic component 1 is mounted is separated. The separation method is not particularly limited, but for example, each electronic component 1 is gripped by a picking device, and the electronic components are divided into individual pieces together with the carrier 2. Alternatively, the electronic components 1 and the carrier 2 can be divided into individual pieces by dicing. That is, the carrier 2 can be cut between adjacent electronic components 1 to be divided into individual pieces.

### 5. Features

The positioning device 5 configured as described above has the following effects.
(1) In the pressure bonding step, to accurately bring the shielding material 42 into close contact with the surface of each electronic component 1, it is necessary to accurately position the shielding material 42 on the lower mold 62. In the present embodiment, in the module C, the shielding material 42 is disposed at a predetermined position on the sheet table 52. Thus, when the sheet material 4 is transferred from the sheet table 52 to the lower mold 62, the positioning of the shielding material 42 to the lower mold 62 is already completed. Thus, in the pressure bonding step, the shielding material 42 can be accurately pressure-bonded to the electronic component 1 without positioning the shielding material 42.
(2) In the present embodiment, the end edges of two orthogonal sides of the shielding material 42 are detected by using the two sensors 532 and 533. Thus, the position of the shielding material 42 in the plane direction can be accurately detected. When the shielding material 42 is not positioned within a predetermined range, the shielding material 42 can be disposed at a predetermined position on the sheet table 52 by driving at least one of the support mechanism 51 and the sheet table 52.
(3) Since the sensor unit 53 is provided with the first pressing part 534, the first pressing part 534 can be pressed against the sheet table 52 in addition to the detection of the position of the shielding material 42 by descending the sensor unit 53. This makes it possible to sandwich the sheet material 4 between the first pressing part 534 and the sheet table 52. Thus, it is not necessary to separately provide a mechanism for pressing the sheet material 4 at the time of cutting.

### 6. Modification

Although one embodiment of the present invention has been described above, the present invention is not limited to the above embodiment, and various modifications can be made without departing from the gist thereof. For example, the following modifications are possible. The substances of the modifications described below can be appropriately combined.
(1) In the above embodiment, the sheet material 4 is unwound from the roll 40, and the shielding material 42 is positioned on the sheet table 52 and then cut to form the sheet-like sheet material 4. However, the sheet-like sheet material 4 on which one shielding material 42 is disposed may be prepared and positioned on the sheet table 52.

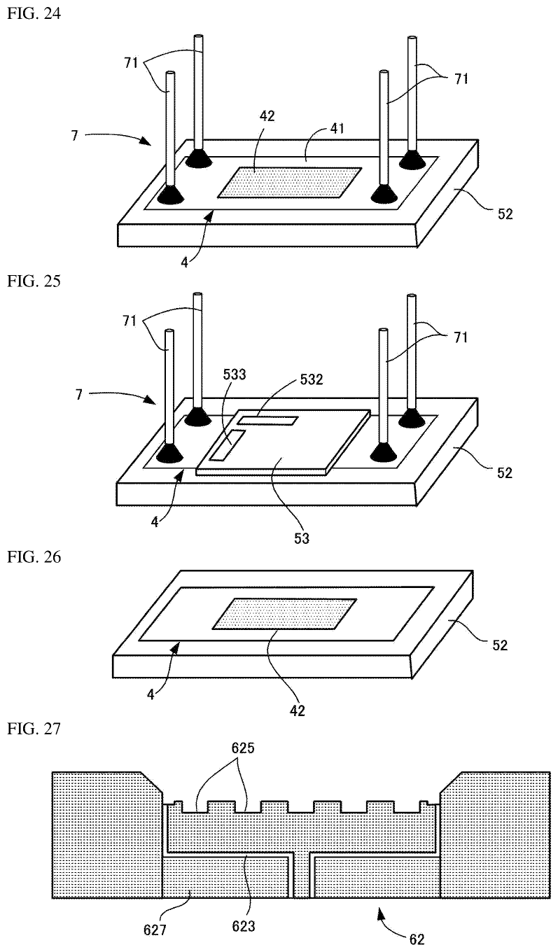

For example, as illustrated in FIG. 23, the conveyance unit 7 including four rod-shaped suction members 71 moves to an initial position where the sheet-like sheet materials are stacked. After the suction members 71 suck the four corners of the uppermost sheet material 4, the sheet material 4 is disposed above the sheet table 52 as illustrated in FIG. 24. Next, as illustrated in FIG. 25, the sensor unit 53 is disposed on the sheet material 4, and the position of the shielding material 42 is detected. As the detection method, for example, a method using the two sensors 532 and 533 as described in the above embodiment may be adopted. At this time, when the position of the shielding material 42 is not within a predetermined range, the conveyance unit 7 moves in the horizontal direction, and the shielding material 42 is positioned at a predetermined position of the sheet table 52.

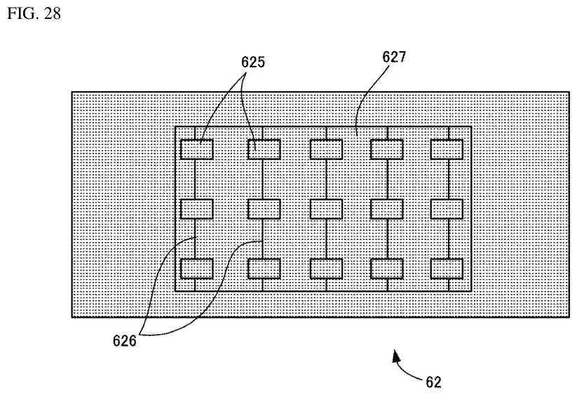

Subsequently, after the sensor unit 53 is retracted from above the sheet material 4, the conveyance unit 7 descends. Then, as illustrated in FIG. 26, the sheet material 4 is sucked to the sheet table 52, and then the conveyance unit 7 is separated from the sheet material 4. The sheet material 4 for which the positioning of the shielding material 42 is performed is thus disposed on the sheet table 52. Thereafter, the conveyance unit 7 returns to the initial position where the sheet-like sheet materials 4 are stacked, and the same processing is repeated.
(2) In the above embodiment, when the sheet material 4 is positioned in the front-back direction, the sheet table 52 is moved in the front-back direction. However, positioning in the front-back direction may also be performed by, for example, simultaneously moving the roll holder 511 and the feeder 512 in the front-back direction while synchronizing the roll holder and the feeder.
(3) In the above embodiment, the two sensors 532 and 533 detects the position of the shielding material 42. However, as long as the position of the shielding material 42 with respect to the sheet table 52 can be detected, the type, position, and number of sensors are not particularly limited, and various modes are possible. Thus, the sensor may be provided not on the base 531 but on, for example, the sheet table 52 or other members.
(4) In the above embodiment, the first pressing part 534 is provided on the base 531 of the sensor unit 53. However, the first pressing part may be provided at another portion without being provided on the sensor unit 53.
(5) In the above embodiment, in the module B, the electronic component 1 is disposed on the upper mold 61 and the sheet material 4 is disposed on the lower mold 62, but this may be reversed.
(6) The lower mold 62 on which the sheet material 4 is disposed may be in another mode, for example, as illustrated in FIGS. 27 and 28. As illustrated in FIGS. 27 and 28, no support plate is disposed on the lower mold 62, and a recess 625 is directly formed on the upper surface of the base 627 of the lower mold 62. In addition to the suction port 623 described above, a plurality of suction ports 626 are formed on the upper surface of the base 627 to suck the sheet material 4. As illustrated in FIG. 28, these suction ports 626 are formed in a linear shape so as to connect the recesses 625 between the recesses 625 adjacent in one direction (up-down direction in FIG. 28). The sheet material 4 can be firmly fixed by the linear suction port 626. The configuration of the lower mold 62 may be other than this, and the position, form, and number of suction ports are not particularly limited as long as the sheet material 4 can be firmly fixed.
(7) In the above embodiment, in the module B, the electronic component 1 is disposed on the upper mold 61 and the sheet material 4 is disposed on the lower mold 62, but this may be reversed.
(8) In the above embodiment, an example in which the electronic component 1 divided in advance is disposed on the carrier 2, and then the shielding material 42 is pressure-bonded to the electronic component 1 has been described, but the present invention is not limited to this configuration. For example, a semiconductor substrate can be divided into pieces by half cutting, and the divided pieces can be placed on the upper mold 61. Then, when the upper mold 61 and the lower mold 62 are brought close to each other after the sheet material 4 is disposed on the lower mold 62 as described above, the shielding material can be brought into close contact with the groove formed by half cutting and the top surface of the semiconductor substrate. The shield layer can be thus formed. Thereafter, dicing is performed along the groove, whereby electronic components separated into individual pieces on which the shield layer is formed can be obtained.
(9) In the above embodiment, the positioning device 5 that positions the shielding material 42 in the sheet material 4 including the base material 41 and the shielding material 42 disposed on the base material 41 has been described, but the configuration of the sheet material 4 is not limited to this. That is, the present invention can be applied to all sheet materials including a base material and a sheet-like functional material having a size smaller than the base material and disposed on the base material. That is, the present invention can be applied to all processes in which it is necessary to position a functional material having a predetermined function with respect to a sheet table with high accuracy. The process after positioning can also be applied to various processes other than the above-described pressure bonding.

### REFERENCE SIGNS LIST

1 Electronic component
2 Carrier
4 Sheet material
41 Base material
42 Shielding material (functional material)
5 Positioning device
51 Support mechanism
52 Sheet table
53 Sensor unit (detection part)
532, 533 Sensor
534 First pressing part
54 Cutting mechanism

1. A positioning device for a sheet material including a base material and a functional material having a sheet shape disposed on the base material, the positioning device comprising:
a support mechanism that supports the sheet material;
a sheet table that fixes the sheet material; and
a detection unit that detects a position in a plane direction of the functional material in the sheet material supported by the support mechanism,
wherein
the functional material is fixed to the sheet table after positioning of relatively moving the sheet material with respect to the sheet table is completed such that the functional material is disposed at a predetermined position with respect to the sheet table based on the position of the functional material detected by the detection unit.

2. The positioning device for a sheet material according to claim 1, wherein
the support mechanism includes:
a roll holder that holds a roll that is the sheet material that has been wound; and
a feeder that unwinds the sheet material while holding an end of the sheet material wound as the roll,
a plurality of the functional materials are disposed on the base material of the sheet material at an interval in an unwinding direction, and
the positioning device further comprising a cutting part that cuts the sheet material that has been unwound from the roll after the positioning of the sheet material that has been unwound is completed.

3. The positioning device for a sheet material according to claim 2, wherein the detection unit detects a position of an end edge of the functional material in a first direction in which the sheet material is unwound and a second direction orthogonal to the first direction.

4. The positioning device for a sheet material according to claim 3, wherein
the detection unit includes a pressing part for pressing the sheet material that has been unwound,
the detection unit moves up and down from above with respect to the sheet material that has been unwound, and
after the positioning, the detection unit descends, and the cutting part performs cutting in a state where the sheet material that has been unwound is sandwiched between the pressing part and the sheet table.

5. The positioning device for a sheet material according to claim 1, wherein the positioning is performed by moving at least one of the support mechanism and the sheet table.

6. A method for positioning a sheet material including a base material and a functional material disposed on the base material, the method comprising:
disposing the sheet material above a sheet table;
detecting a position in a plane direction of the functional material in the sheet material;
performing positioning of relatively moving the sheet material with respect to the sheet table based on the position of the functional material that has been detected such that the functional material is disposed at a predetermined position with respect to the sheet table; and
fixing the sheet material to the sheet table after the positioning is completed.

7. A method for forming a shield layer with respect to an electronic component, the method comprising:
preparing a first mold and a second mold that face each other;
after the method for positioning a sheet material according to claim 6, conveying the sheet material from the sheet table via a conveyance mechanism to dispose the sheet material on an installation surface of the first mold in a state where the functional material faces the second mold;
disposing a plurality of electronic components on a carrier at a predetermined interval;
disposing the carrier on an installation surface of the second mold in a state where the electronic components face the first mold; and
bringing the first mold and the second mold close to each other, and pressure-bonding the functional material against surfaces of the electronic components to form a shield layer on the surface of the electronic components,
wherein the functional material is an electromagnetic wave shielding material.
